(19) United States
(12) Patent Application Publication
(10) Pub. No.: US 2006/0104150 A1
(43) Pub. Date: May 18, 2006

(54) Semiconductor memory device

(75) Inventors: Hiroyasu Yoshida, Tokyo (JP); Kanji Oishi, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC

(21) Appl. No.: 11/271,816

(22) Filed: Nov. 14, 2005

(30) Foreign Application Priority Data
Nov. 15, 2004 (JP) 2004-330456

(51) Int. Cl. G11C 8/00

(52) U.S. Cl. 365/233

(57) ABSTRACT

The present invention relates to a semiconductor memory device operating synchronously with a clock signal. The memory device includes a circuit for converting an external command signal supplied via an external terminal into an internal command signal including latency and outputting a detection signal when a collision between the internal command signals occurs.

This application claims priority to prior application JP 2004-330456, the disclosure of which is incorporated herein by reference.

### BACKGROUND OF THE INVENTION

The present invention relates to semiconductor memory devices operating in synchronization with clock signals and, more particularly, to a double data rate (DDR) type synchronous dynamic random access memory (SDRAM) device.

As processors are increasing in operating frequency, it is required to increment the rate of data transfer of a DRAM device. For this purpose, a synchronous dynamic random access memory (SDRAM) device, which operates synchronously with a clock signal, has been developed. Further, a double data rate (DDR) type SDRAM device, which transfers data at both of the rising edge and the falling edge of a clock signal, has been developed. Consequently, the DDR type SDRAM (DDR-SDRAM) device has double the data transfer rate compared to the regular SDRAM device. The DDR-SDRAM devices include a DDR1-SDRAM device and a DDR2-SDRAM device, which is the evolutionary step from the DDR1-SDRAM device.

In the DDR1-SDRAM device, a write latency WL is a fixed value of “1” (i.e., WL=1). The write latency WL means the number of clock cycles (tCK) required from a time when a write command and an address (address signal) are input to a semiconductor memory device to a time when data to be written in the address is supplied to the semiconductor memory device.

In the DDR2-SDRAM device of a new standard, the number of prefetch is four bits and a minimum interval for column command input corresponds to 2 clock cycles. In the DDR2-SDRAM device, the write latency WL is defined by an additive latency AL which is variable. Accordingly, the write latency WL is variable and is expressed as WL=AL+CL−1. Under present circumstances, when the additive latency AL is 4 (AL=4) and a CAS latency CL is 5 (CL=5), the maximum value of the write latency WL is 8 (WL=4+5−1=8).

In the DDR2-SDRAM device, after a lapse of (WL+2tCK) since the input of a write command to the semiconductor memory device, data is written to a memory cell at a specified address. Assuming that the write latency WL is, e.g., 8 (WL=8), the DDR2-SDRAM device has latency (waiting time) including 8 (=WL) clock cycles from a first clock cycle, in which a write command is input to the semiconductor memory device, to an eighth clock cycle and 2 clock cycles (2tCK) subsequent to the eighth clock cycle. In the next one clock cycle, the write command and an address are transmitted to an inner part of the semiconductor memory device, thus starting the write operation. For the reason, data is written to a memory cell at a specified address after a lapse of 11tCK. Therefore, the semiconductor memory device requires an address latch circuit for latching an address for a period of 11tCK.

FIG. 1 shows an address latch circuit for the above-mentioned DDR2-SDRAM device. Referring to FIG. 1, the address latch circuit includes an input buffer 110, a command generation circuit 120 connected to the input buffer 110, a column address latch circuit 130, and a YS (column selection) latch circuit 140. The address latch circuit latches an input address for a predetermined period of clock cycles and then outputs a column address CAT and a YS (column selection) control signal MDCAYST.

The input buffer 110 receives a clock input CLK, a command, and an address and then outputs an address PA and a clock PACLK. The command generation circuit 120 decodes a write command received via the input buffer 110 and outputs a decoded output MDCAT. The column address latch circuit 130 receives the clock PACLK, the address PA, and a latency control signal, latches the address PA, and outputs a column address CAT. The YS latch circuit 140 receives the decoded output MDCAT and the latency control signal, latches the decoded output MDCAT, and outputs a YS control signal MDCAYST.

In this instance, each of the column address latch circuit 130 and the YS latch circuit 140 requires an 11-bit counter circuit. Since a period during which an externally supplied address signal is held in the semiconductor memory device (chip) is remarkably extended, disadvantageously, the number of circuits is increased.

Further, after several to ten clock cycles from the input of a read/write command from the outside to the DDR2-SDRAM device, the read/write operation starts in the DDR2-SDRAM device. In addition, latency for a write command differs from that for a read command. Accordingly, when external write and read commands are issued at predetermined intervals, in some cases, internal write and read commands are issued in the same cycle. This means a collision between the internal write and read commands. Although the collision is inhibited as an illegal operation, if a user accidentally allows to cause the illegal operation, the user has to take measures to recover the DDR2-SDRAM device.

Under present circumstances, after a collision between internal commands, e.g., a collision between internal write and read commands, data cannot be read or written from/to a correct address unless an internal reset signal is generated by issuing a mode register set (MRS) command or again turning on power. To avoid the incorrect read/write operation, according to one approach, a command-controlled type address latch circuit for read commands and that for write commands are separately provided. Disadvantageously, the number of address latch circuits increases. Therefore, detecting a collision between internal write and read commands and returning to the normal operation after the collision between the commands are problems.

### SUMMARY OF THE INVENTION

Accordingly, in consideration of the above-mentioned disadvantages and problems, the present invention is to provide a semiconductor memory device including a minimum-size circuit for detecting a collision between an internal read command and an internal write command and, after the occurrence of an illegal operation caused by the collision, executing internal processing in order to allow the semiconductor memory device to normally operate.

The present invention is applied to a semiconductor memory device operating synchronously with a clock signal.

According to a first aspect of the present invention, the memory device includes a circuit for converting an external command signal supplied via an external terminal into an internal command signal including latency and outputs a detection signal when a collision between the internal command signals occurs.

In the memory device according to the first aspect, the memory device further comprises an input address pointer for counting the external command signals and an output address pointer for counting the internal command signals. The detection signal serves to reset the input address pointer and the output address pointer.

In the memory device according to the first aspect, the internal command signals include an internal read command and an internal write command.

According to a second aspect of the present invention, the memory device includes a command generation circuit for converting an external command signal supplied via an external terminal into an internal command signal including latency. The command generation circuit issues a clear command, when a collision between the internal command signals occurs.

In the semiconductor memory device according to the second aspect, also, the memory device further comprises an input address pointer circuit for counting the external command signals and an output address pointer circuit for counting the internal command signals. The clear command resets the input address pointer circuit and the output address pointer circuit.

According to a third aspect of the present invention, the memory device comprises a command generation circuit for converting an external command signal supplied via an external terminal into an internal command signal including latency, an input address pointer circuit for counting the external command signals, an output address pointer circuit for counting the internal command signals, and an address latch circuit for allowing a latch circuit specified by an input address pointer output from the input address pointer circuit to latch an address signal and for allowing a latch circuit specified by an output address pointer output from the output address pointer circuit to output a latched address signal. The command generation circuit generates a clear command, when a collision between the internal command signals occurs. The clear command resets the input address pointer circuit and the output address pointer circuit to recover the operation for specifying a latch circuit in the address latch circuit.

It is preferable that the semiconductor memory device according to the first through third aspects is a DDR2-SDRAM device.

### BRIEF DESCRIPTION OF THE DRAWINGS

FIG. 1 is a block diagram of a clock-controlled type address latch circuit which is proposed as an advanced address latch circuit;

FIG. 2 is a block diagram of a command-controlled type address latch circuit according to the present invention;

FIG. 3 is a diagram of the configuration of a command generation circuit in FIG. 2;

FIG. 4 is a diagram of the configuration of an input address pointer circuit in FIG. 2;

FIG. 5 is a diagram of the configuration of an output address pointer circuit in FIG. 2;

FIG. 6 is a diagram of the configuration of a column address latch circuit in FIG. 2;

FIG. 7 is a waveform chart explaining the operation of the address pointer upon writing according to the present invention;

FIG. 8 is a waveform chart explaining the operation of the address pointer upon reading according to the present invention;

FIG. 9A is a waveform chart explaining the operation of the address pointer upon a collision between a read command and a write command on condition that there is no clear command; and

FIG. 9B is a waveform chart explaining the operation of the address pointer upon a collision between a read command and a write command on condition that a clear command is used.

### DESCRIPTION OF THE PREFERRED EMBODIMENTS

A semiconductor memory device according to the present invention will now be described with reference to the drawings.

An embodiment of the present invention is of a DDR2-SDRAM device including a command-controlled type address latch circuit. The illegal processing operation of the command-controlled type address latch circuit upon a collision between an internal read command and an internal write command will now be described.

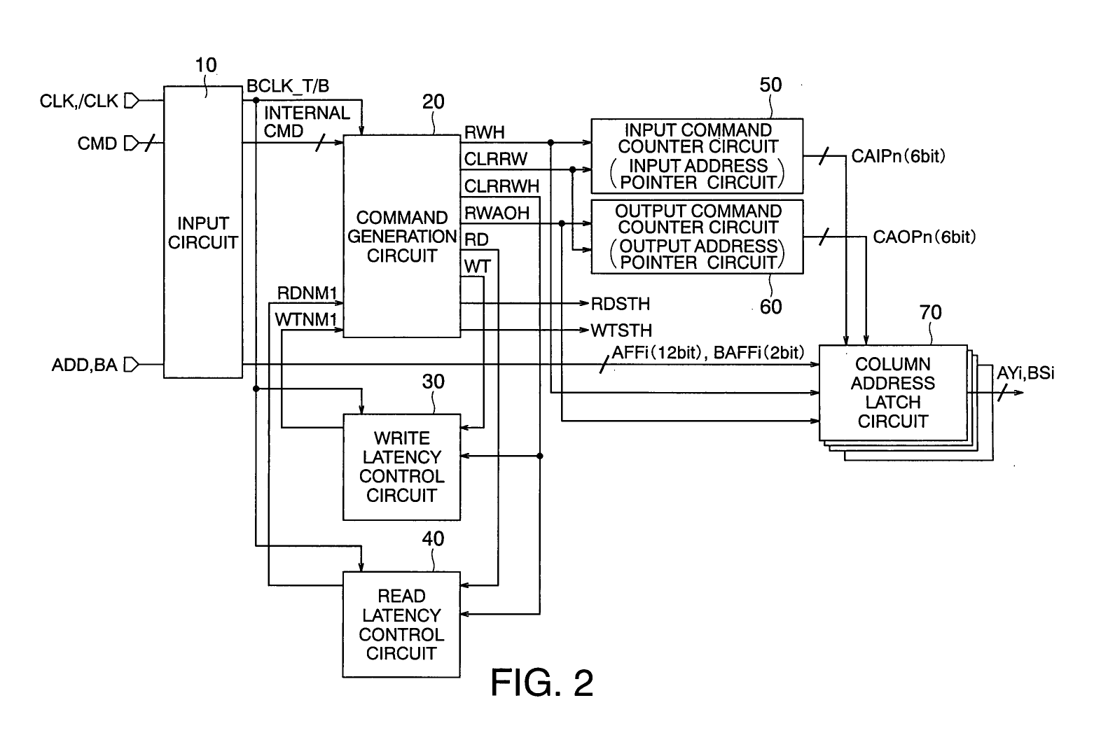

FIG. 2 shows a block diagram of the configuration of the command-controlled type address latch circuit according to the present embodiment of the present invention.

The command-controlled type address latch circuit includes an input circuit 10, a command generation circuit 20, a write latency control circuit 30, a read latency control circuit 40, an input command count circuit (input address pointer circuit) 50, an output command count circuit (output address pointer circuit) 60, and a column address latch circuit 70. The input circuit 10 receives an externally supplied input signal and outputs a control signal. The command generation circuit 20 decodes the control signal. The column address latch circuit 70 comprises a plurality of latch circuits. The input command count circuit 50, the output command count circuit 60, and the column address latch circuit 70 are collectively called an address latch circuit part.

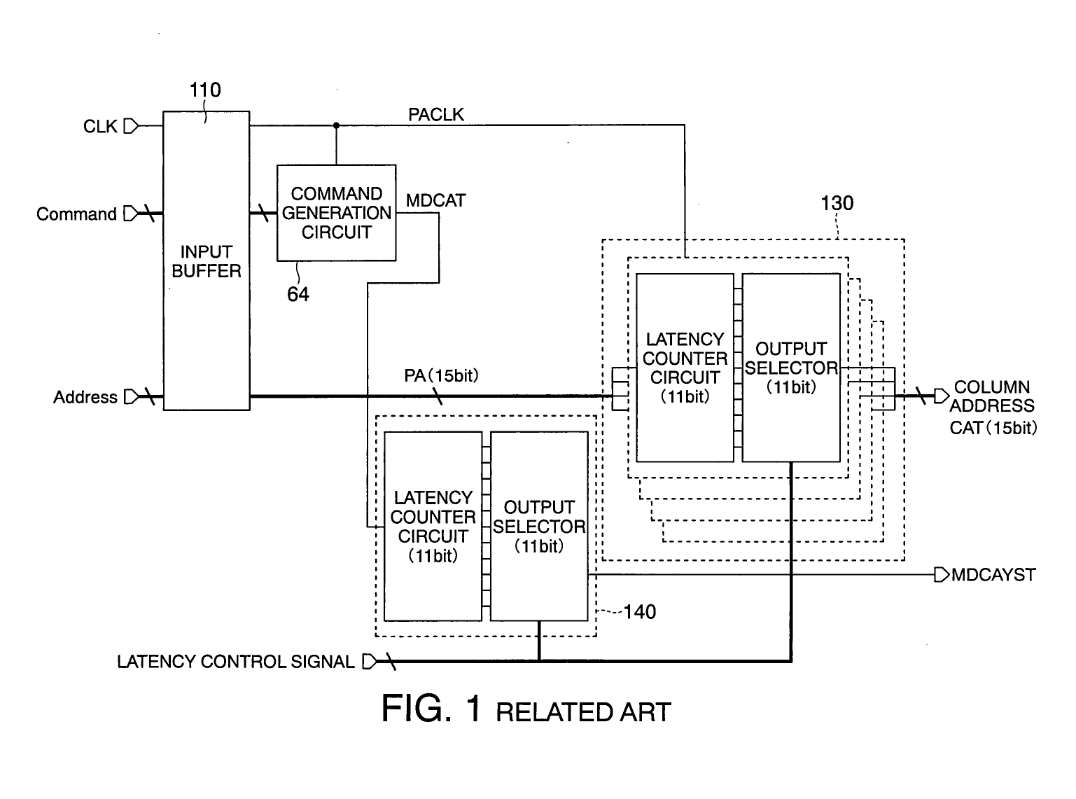

The command-controlled type address latch circuit is based on a system for counting the number of commands and controlling latch time in accordance with the number of counted commands. On the other hand, the address latch circuit, shown as a proposed example in FIG. 1, counts the number of clocks and controls latch time in accordance with the number of counted clocks. Accordingly, the proposed address latch circuit is called a clock-controlled type address latch circuit. The command-controlled type address latch circuit is based on the address latch system designed in consideration of the following point. Column command to Column command delay time (tCCDmin.), which determines a minimum clock cycle time between read commands or write commands, is 2 clock cycles because any DDR2-SDRAM device has four prefetch bits. The number of commands is equal to or lower than half the number of clocks. Since the command-controlled type address latch circuit counts input read and write commands, therefore, the number of latch circuits can be reduced to half that of the clock-controlled type address latch circuit. In addition, the operating frequency can be reduced in half.

The configuration according to the present embodiment is compared with that of the proposed circuit in FIG. 1. The DDR2-SDRAM device shown in FIG. 1 has a latency counter for each address. On the other hand, according to the present embodiment, the latency counter circuits are arranged outside the column address latch circuit, thus reducing the number of circuits. In other words, in the DDR2-SDRAM device in FIG. 1, address latches are linked together and an address is sequentially transferred by clock control. Accordingly, a counter for 11 clock cycles is provided for each address. According to the present embodiment, the latency counter circuits are arranged outside the column address latch circuit, i.e., the input command count circuit 50 and the output command count circuit 60, each of which counts a command every 2 clock cycles, are arranged outside the column address latch circuit 70.

In FIG. 1, the column address latch circuit 130 receives an address every cycle in synchronization with a clock. On the other hand, according to the present embodiment, the input command count circuit 50 and the output command count circuit 60 count externally supplied commands. One of the latch circuits in the column address latch circuit 70 is selected using a pointer output of the input command count circuit 50 and an address is input to the selected latch circuit. On the other hand, one of the latch circuits in the column address latch circuit 70 is selected using a pointer output of the output command count circuit 60 and a latched address is output from the selected latch circuit.

Since the minimum interval between column commands in the DDR2-SDRAM device is 2 clock cycles, the operating frequency of the command-controlled type address latch circuit can be reduced to half that of the clock-controlled type address latch circuit. In addition, the number of latch circuits can be reduced. The reductions in the number of latch circuits and the operating frequency result in reductions in layout area and power consumption.

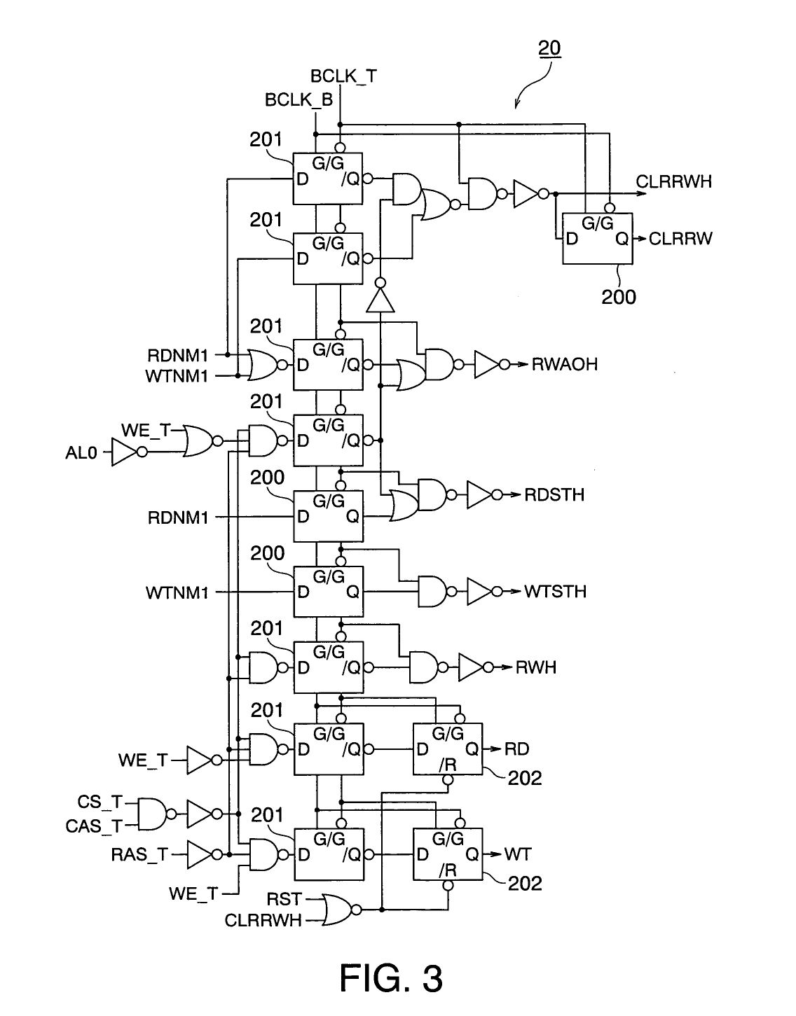

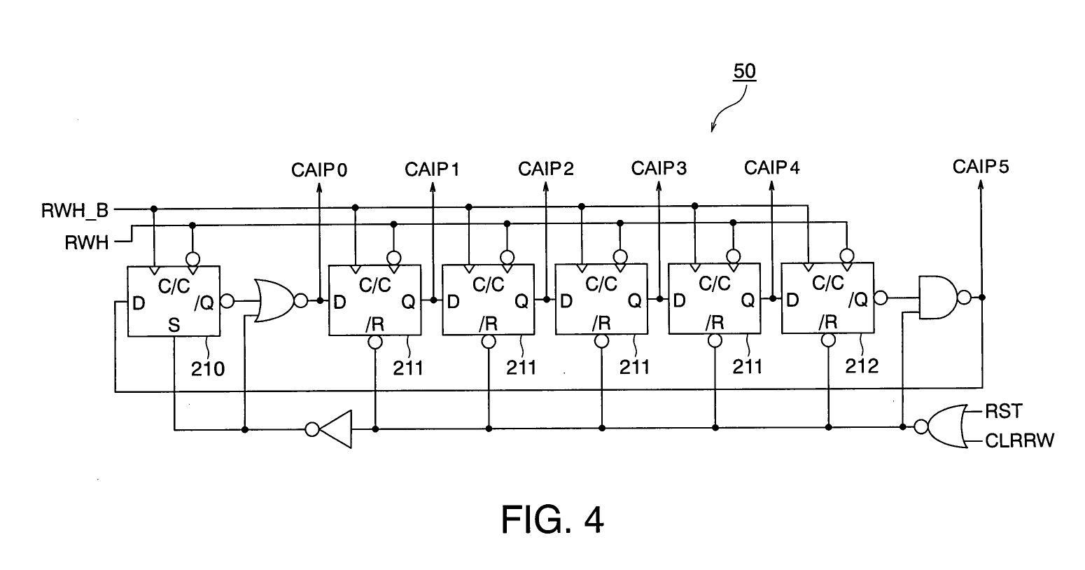

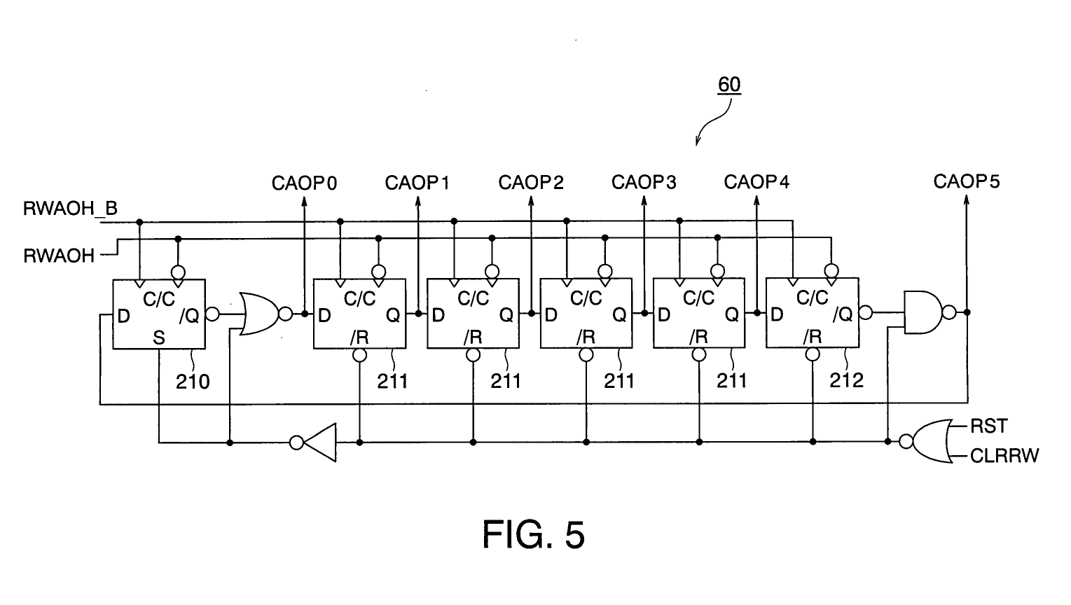

Referring to FIG. 3, each circuit 200 is a level sense type D latch circuit, each circuit 201 is a level sense type D latch circuit 201 whose output is inverted, and each circuit 202 is a level sense type D latch circuit having a reset terminal. Referring to FIGS. 4 and 5, each circuit 210 is an edge trigger type D flip-flop circuit having a set terminal, each circuit 211 is an edge trigger type D flip-flop circuit having a reset terminal, and each circuit 212 is an edge trigger type D flip-flop circuit having a reset terminal. An output of each of the circuits 210 and 212 is inverted. In any circuit, the mark “◯” at an input/output denotes an inverting input/output terminal.

The input circuit 10 receives clocks CLK and /CLK, commands CMD (/CS, /RAS, /CAS, /WE), an address ADD, and a bank address BA. The input circuit 10 outputs internal clock signals BCLK_T and BCLK_B and internal commands (CS_T, RAS_T, CAS_T, WE_T) to the command generation circuit 20. In addition, the input circuit 10 outputs internal address signals AFFi and BAFFi to the column address latch circuit 70. In the following description regarding the respective circuits, only the essential configuration and operation of the SDRAM device according to the present invention will be explained because the general operation of the SDRAM device is well known.

FIG. 3 shows the command generation circuit 20 which decodes the internal commands supplied from the input circuit 10 and outputs external read/write commands (RD or WT, and RTH). In addition, when a flag (RDNM1 or WTNM1) is issued from the read latency control circuit 40 or the write latency control circuit 30, the command generation circuit 20 issues internal read/write commands (RDSTH or WTSTH, and RWAOH). In the following description, a read/write command supplied via a terminal will be called an external read/write command. A read/write command, which is issued in the semiconductor memory device after a latency set based on an additive latency AL and a CAS latency, will be called an internal read/write command.

The read latency control circuit 40 outputs a flag RDNM1 indicating that an internal read command will be issued in the next cycle. The write latency control circuit 30 outputs a flag WTNM1 indicating that an internal write command will be issued in the next cycle. A flag AL0 indicates that the additive latency AL is set to 0. A reset signal RST is generated when the power is turned on or when a mode register set (MRS) command is issued.

A command RD is issued when an external read command is supplied. A command WT is issued when an external write command is supplied. A command RWH is issued when an external read or write command is supplied. An internal read command RDSTH is issued after a set latency. An internal write command WTSTH is issued after the set latency. A command RWAOH is issued when an internal read or write command is supplied. A clear command CLRRWH is issued when a collision between an internal read command and an internal write command is detected. A clear command CLRRW is obtained by holding the clear command CLRRWH for one cycle.

The write latency control circuit 30 includes a shift register circuit. The write latency control circuit 30 receives the external write command (WT), counts the number of clocks set based on the additive latency AL and the CAS latency CL, and outputs the flag (WTNM1) in the cycle previous to the cycle when an internal write command is issued. The read latency control circuit 40 includes a shift register circuit. The read latency control circuit 40 receives the external read command (RD), counts the number of clocks set based on the additive latency AL, and outputs the flag (RDNM1) in the cycle previous to the cycle when an internal read command is issued.

FIG. 4 shows the input command count circuit (input address pointer circuit) 50 and FIG. 5 shows the output command count circuit (output address pointer circuit) 60. The input command count circuit 50 counts external read/write commands RWH and generates a pointer signal CAIPn to select one of the latch circuits in the column address latch circuit 70. The output command count circuit 60 counts internal read/write commands RWAOH and generates a pointer signal CAOPn to select one of the latch circuits in the column address latch circuit 70.

The input command count circuit 50 receives external read/write commands RWH and RWH_B as clocks. The output command count circuit 60 receives internal read/write commands RWAOH and RWAOH_B as clocks. Each of the circuits 50 and 60 is initialized to pointer 0 in response to a reset signal RST which is generated when the power is turned on or when an MRS command is issued.

The input command count circuit (input address pointer circuit) 50 has a 6-bit configuration. Each time an external read/write command (RWH) is issued, the value n of the pointer output CAIPn is shifted in this order of 0→1→2→3→4→5→0. In response to the pointer output CAIPn, the corresponding latch circuit in the column address latch circuit 70 receives an address. After the address is supplied, the value of the pointer is changed. The output command count circuit (output address pointer circuit) 60 has a 6-bit configuration. Each time an internal read/write command (RWAOH) is issued, the value n of the pointer output CAOPn is shifted in this order of 0→1→2→3→4→5→0. In response to the pointer output CAOPn, the corresponding latch circuit in the column address latch circuit 70 outputs an address. An output latch circuit (not shown) latches the address and outputs the address to an inner part of the semiconductor memory device. After the address is output, the value of the pointer is changed.

When each of the input command count circuit (input address pointer circuit) 50 and the output command count circuit (output address pointer circuit) 60 receives the reset signal RST output upon generating the MRS command or the clear command CLRRW, the pointer output is initialized, i.e., reset to 0. In this case, each command count circuit (address pointer circuit) has a 6-bit configuration. The number of bits corresponds to the number of commands to be latched. Accordingly, the 6-bit configuration can be varied as necessary.

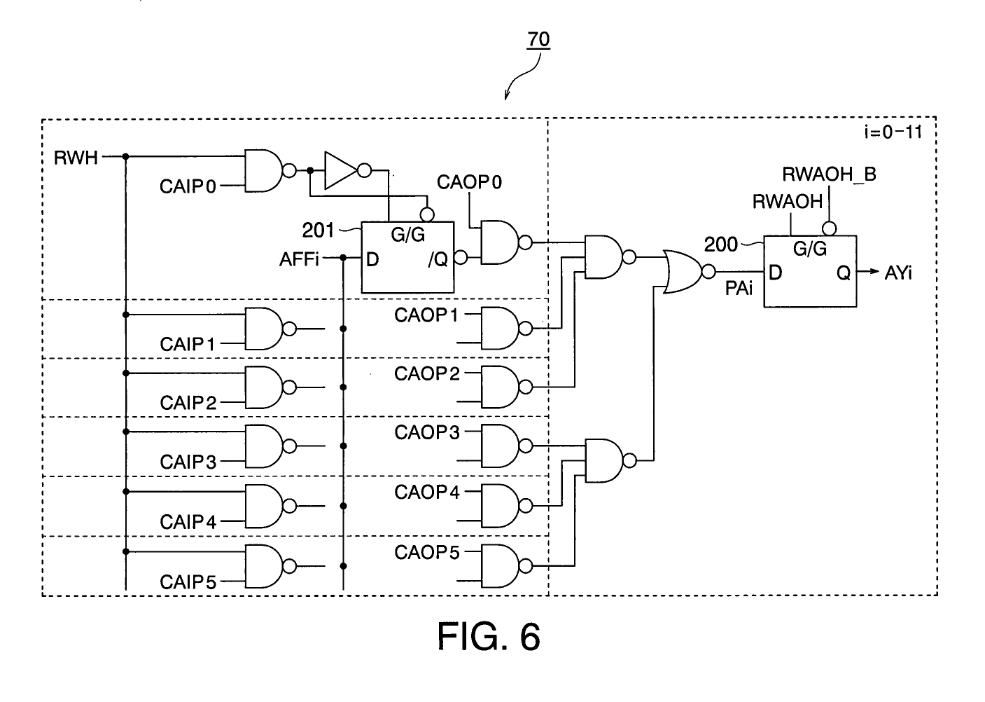

FIG. 6 shows the column address latch circuit 70 including six latches for each address (AFFi) or bank address (BAFFi). When the external read/write command (RWH) is issued, only the gate input of a latch circuit, which is selected by the input command count circuit (input address pointer circuit) 50 (i.e., to which the signal CAIPn at a level “High” is supplied), is valid and the column address (AFFi) is supplied to the valid gate input. In this case, the column address latch circuit 70 has a 6-bit configuration, which corresponds to a period to hold a latched address (i.e., the number of commands) and can be changed as needed.

When an NAND logic operation is performed on the pointer output of the output command count circuit (output address pointer circuit) 60 and a latch output, the output (address) of the latch circuit, which is selected by the output command count circuit (output address pointer circuit) 60 (i.e., to which the signal CAOPn in the level “High” is supplied), is valid. When an internal read/write command (RWAOH) is issued, the selected column address is supplied to the output latch circuit and is then output to the inner part of the semiconductor memory device.

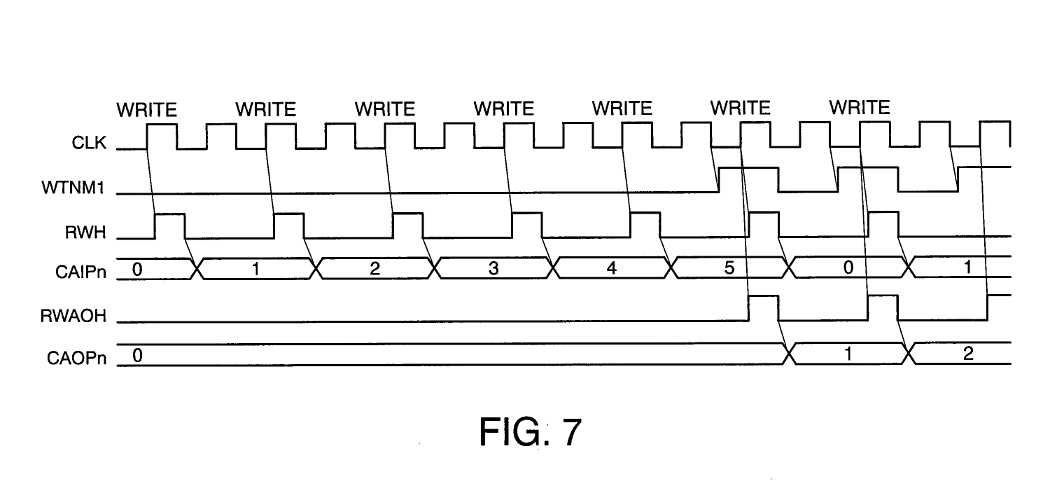

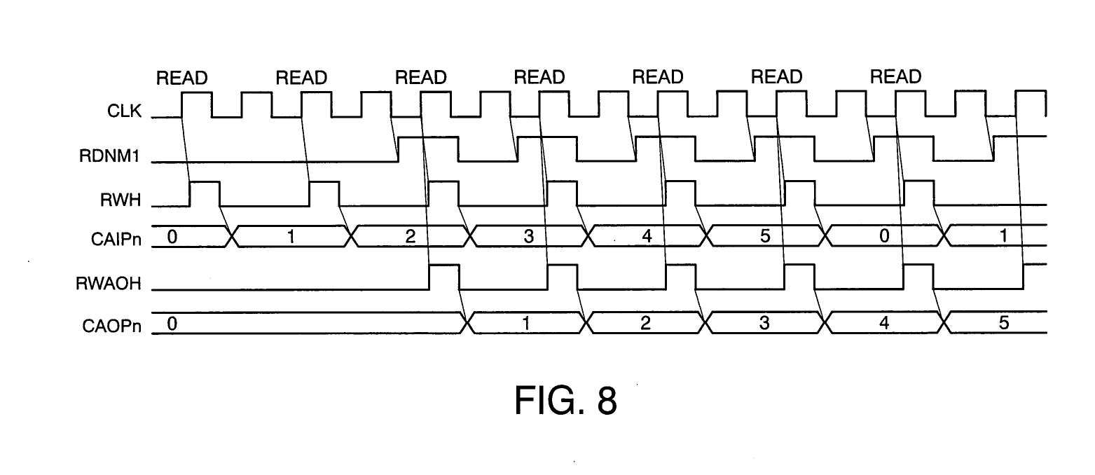

As mentioned above, a column address received when an external read/write command is issued is output when the corresponding internal read/write command is issued. FIGS. 7 and 8 show the above-mentioned situation. FIG. 7 shows waveforms upon writing. FIG. 8 shows waveforms upon reading. It is assumed that the additive latency AL=4 and the CAS latency CL=5.

Referring to FIG. 7, upon writing, an external write command is issued every 2 clock cycles from the first clock cycle. The value n of the output CAIPn of the input command count circuit (input address pointer circuit) 50 is 0 and is then shifted synchronously with the external write command in the order of 1, 2, 3, 4, 5. In this case, since the write latency WL is 8 (i.e., WL=8), an internal write command is issued in the eleventh clock cycle that is delayed by 2 clock cycles from the write latency WL. The value n of the output CAOPn of the output command count circuit (output address pointer circuit) 60 is 0 and is then shifted synchronously with the internal write command in the order of 1, 2, 3, 4, 5. Thus, internal circuitry performs the write operation.

Referring to FIG. 8, upon reading, an external read command is issued every 2 clock cycles from the first clock cycle. The value n of the output CAIPn of the input command count circuit (input address pointer circuit) 50 is 0 and is then shifted synchronously with the external read command in the order of 1, 2, 3, 4, 5. In this case, since the additive latency AL is 4 (i.e., AL=4), an internal read command is issued in the fifth clock cycle. The value n of the output CAOPn of the output command count circuit (output address pointer circuit) 60 is 0 and is then shifted synchronously with the internal read command in the order of 1, 2, 3, 4, 5. Thus, the internal circuitry performs the read operation.

As mentioned above, the input address pointer and the output address pointer are shifted in relation to each other and a column address received upon issuing an external command is output upon issuing an internal command, so that the command-controlled type address latch circuit can be normally operated.

If an internal read command collides with an internal write command, the input address pointer is shifted twice but the output address pointer is shifted only once. Therefore, in circuitry without using a clear command CLRRW, after the collision between the internal read and write commands, the relation between the input and output address pointers is lost. Unfortunately, the read and write operations cannot be performed in correct addresses.

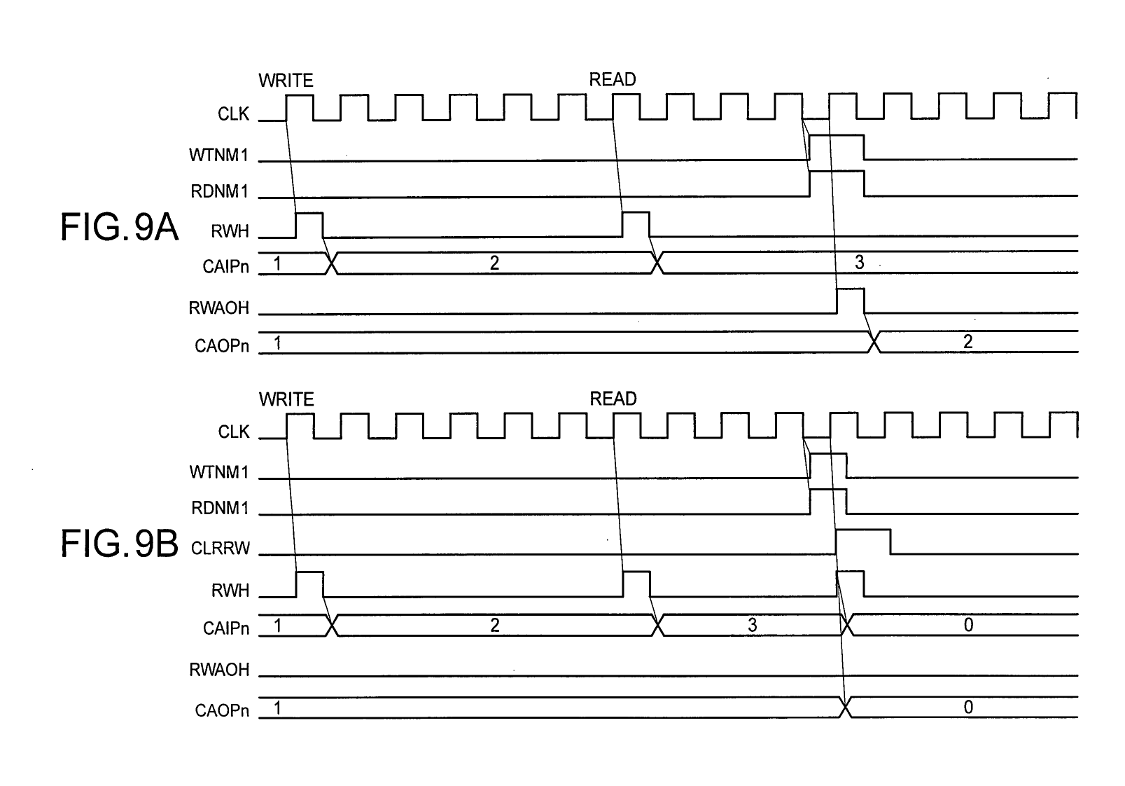

FIG. 9A shows the above-mentioned situation. It is assumed that the additive latency AL is 4 (i.e., AL=4), the CAS latency CL is 5 (CL=5), an external write command is input in the first clock cycle, and an external read command is input in the seventh clock cycle.

When the external write command is issued in the first clock cycle, the value n of the pointer output CAIPn is 2 (i.e., n=2). When the external read command is issued in the seventh clock cycle, the value n of the pointer output CAIPn is 3 (i.e., n=3). In response to those external commands, the flag WTNM1 and the flag RDNM1 are simultaneously output from the write latency control circuit 30 and the read latency control circuit 40, respectively. Accordingly, the value n of the pointer output CAOPn is 2, i.e., the value is increased by only one. Consequently, the value n of the output of the input command count circuit (input address pointer circuit) 50 is 3 (n=3) and that of the output command count circuit (output address pointer circuit) 60 is 2 (n=2), i.e., the relation therebetween is lost. Since a pointer output for address input differs from that for address output, the read and write operations cannot be subsequently performed in correct addresses.

FIG. 9A shows the situation without using the clear command CLRRW. FIG. 9B shows waveforms obtained when the clear command CLRRW is used according to the present invention. It is assumed that the additive latency AL is 4 (AL=4), the CAS latency CL is 5 (CL=5), an external write command is input in the first clock cycle, and an external read command is supplied in the seventh clock cycle.

Referring to FIG. 9B, when the external write command is issued in the first clock cycle, the value n of the pointer output CAIPn is 2 (n=2). When the external read command is issued in the seventh clock cycle, the value n of the pointer output CAIPn is 3 (n=3). In response to those external commands, the flag WTNM1 and the flag RDNM1 are simultaneously output from the write latency control circuit 30 and the read latency control circuit 40, respectively. Consequently, the clear command CLRRW is output from the command generation circuit 20. In response to the clear command CLRRW, the pointer output CAIPn of the input command count circuit (input address pointer circuit) 50 and the pointer output CAOPn of the output command count circuit (output address pointer circuit) 60 are reset, i.e., the value n of each output is reset to 0 (n=0). After that, the read and write operations can be performed in correct addresses.

In the circuit configuration according to the present invention, unless AL=0, when the flag RDNM1 and the flag WTNM1 are simultaneously output from the read latency control circuit 40 and the write latency control circuit 30, the clear command CLRRW is issued. When AL=0, so long as the flag WTNM1 is generated and an external read command (i.e., internal read command) is supplied, the clear command CLRRW is also issued. In other words, when a collision between an internal read command and an internal write command occurs, the collision is detected and the command generation circuit 20 issues clear commands (CLRRW, CLRRWH). The clear command is supplied each address pointer circuit, thus resetting the pointer output to 0.

As shown in FIG. 2, the clear command (CLRRWH) is supplied to each of the read latency control circuit 40 and the write latency control circuit 30, thus resetting a read command held by the read latency control circuit 40 and a write command held by the write latency control circuit 30. The reason is that the correspondences between respective addresses and the read and write commands held by the respective circuits 40 and 30 are lost.

As mentioned above, when a collision between internal read and write commands is detected, the command-controlled address latch circuit is reset. Advantageously, after the collision, the correspondence between a newly supplied read/write command and the corresponding address is correctly held, so that data can be read or write from/to a correct address.

According to the present invention, the address latch circuit part includes the column address latch circuit 70, the input command count circuit (input address pointer circuit) 50, and the output command count circuit (output address pointer circuit) 60. The input command count circuit 50 counts the number of external commands and outputs a pointer signal to specify any latch circuit for latching an address in the column address latch circuit 70. The output command count circuit 60 counts the number of internal commands and outputs a pointer signal to specify any latch circuit for outputting a latched address in the column address latch circuit 70. According to the present invention, instead of a clock-controlled type address latch circuit for counting the number of clocks and performing the control operation, the command-controlled type address latch circuit for counting the number of commands and performing the control operation is used. Advantageously, the number of latch circuits can be reduced and the operating frequency can also be lowered.

Further, the command generation circuit 20 detects a collision between internal commands and generates a clear command. In response to the clear command, the input and output address pointer circuits are initialized. Thus, the read/write operation can be recovered after the collision.

The present invention realizes a semiconductor memory device with minimum circuitry which is capable of operating at a low frequency, detecting a collision between internal commands, and when the illegal operation is caused by the collision, operating normally.

Having described the preferred embodiment of the present invention, it should be understood that the present invention is not limited to the embodiment and various modifications thereof could be made without departing from the spirit and scope of the invention.

What is claimed is:

1. A semiconductor memory device operating synchronously with a clock signal, the memory device including:
a circuit for converting an external command signal supplied via an external terminal into an internal command signal including latency and outputting a detection signal when a collision between the internal command signals occurs.

2. The semiconductor memory device according to claim 1, wherein the memory device further comprises an input address pointer for counting the external command signals and an output address pointer for counting the internal command signals, the detection signal resetting the input address pointer and the output address pointer.

3. The semiconductor memory device according to claim 2, wherein the internal command signals include an internal read command and an internal write command.

4. A semiconductor memory device operating synchronously with a clock signal, the memory device including:
a command generation circuit for converting an external command signal supplied via an external terminal into an internal command signal including latency, wherein
when a collision between the internal command signals occurs, the command generation circuit issues a clear command.

5. The semiconductor memory device according to claim 4, wherein the memory device further comprises an input address pointer circuit for counting the external command signals, and an output address pointer circuit for counting the internal command signals, the clear command resetting the input address pointer circuit and the output address pointer circuit.

6. A semiconductor memory device operating synchronously with a clock signal, the memory device comprising:
a command generation circuit for converting an external command signal supplied via an external terminal into an internal command signal including latency;
an input address pointer circuit for counting the external command signals;
an output address pointer circuit for counting the internal command signals; and
an address latch circuit for allowing a latch circuit specified by an input address pointer output from the input address pointer circuit to latch an address signal and for allowing a latch circuit specified by an output address pointer output from the output address pointer circuit to output a latched address signal, wherein
when a collision between the internal command signals occurs, the command generation circuit generates a clear command and the clear command resets the input address pointer circuit and the output address pointer circuit to recover the operation for specifying a latch circuit in the address latch circuit.

7. The semiconductor memory device according to claim 6, wherein the semiconductor memory device is a DDR2-SDRAM device.
